(19) United States
(12) Patent Application Publication
(10) Pub. No.: US 2026/0016237 A1
(43) Pub. Date: Jan. 15, 2026

(54) HEAT DISSIPATION ASSEMBLY

(71) Applicant: SAGEMCOM BROADBAND SAS, BOIS-COLOMBES (FR)

(72) Inventors: Nathan JEANROT, BOIS-COLOMBES (FR); Laurent BEAUTE, BOIS-COLOMBES (FR)

(21) Appl. No.: 19/222,979

(22) Filed: May 29, 2025

(30) Foreign Application Priority Data
May 30, 2024 (FR) 2405631

(51) Int. Cl. F28D 21/00

(52) U.S. Cl. CPC F28D 21/00; F28D 2021/0029; F28F 2255/08; F28F 2255/16

(57) ABSTRACT

A heat sink assembly including a base plate comprising at least one opening and attachment elements for maintaining an electronic component opposite the at least one opening, and a heat sink independent of the base plate and comprising at least one thermal switch inserted through the at least one opening and arranged to be in thermal contact with the electronic component.

### CROSS-REFERENCE TO RELATED APPLICATION

The present application claims priority to French Application No. 2405631 filed with the Intellectual Property Office of France on May 30, 2024, which are incorporated herein by reference in its entirety for all purposes.

### TECHNICAL FIELD

The present invention typically relates to a heat sink assembly, an electronic device containing at least one such heat sink assembly and a manufacturing method for manufacturing such a heat sink assembly and such an electronic device.

### STATE OF THE ART

Heat sinks are known in the prior art. However, these systems can have disadvantages linked to a heavy weight, high cost and/or limited thermal performance.

### SUMMARY OF THE INVENTION

One aim of the present description is to address the above-mentioned disadvantages of the prior art and in particular, firstly, to offer an inexpensive heat sink assembly allowing high heat dissipation and a reduction in the weight of the heat sink assembly and/or electronic apparatus containing it.

To this end, a first aspect of the description relates to a heat sink assembly comprising:
a base plate comprising at least one opening and at least one attachment element for maintaining an electronic component opposite the at least one opening,
a heat sink independent of the base plate and comprising at least one thermal switch inserted through the at least one opening and arranged to be in thermal contact with the electronic component.

In an assembled configuration, the heat sink is substantially located on a first face of the base plate while the electronic component and the thermal switch are located on a second face of the base plate opposite the first face. Preferentially, the thermal switch protrudes from the base plate.

Such a two-part heat sink assembly can be both lightweight, inexpensive to manufacture and to integrate and achieve good thermal performance. The base plate may have a structural support function and/or a thermal function of dissipating thermal energy while the heat sink may be limited to heat dissipation. For example, a first manufacturing method can be used for the base plate and a second manufacturing method can be used for the heat sink. Thus, the base plate can be a deep-drawn sheet and the heat sink can be extruded or molded.

Advantageously, the heat sink is provided as a single unit to reduce costs and optimize thermal performance. Additionally, the heat sink can comprise a relief opposite the thermal switch, the relief maximizing heat exchange with the surrounding atmosphere. This relief can comprise studs, strips, fins, or else channels or trenches.

Advantageously, the thermal switch comprises a contact surface arranged to be in thermal contact with the electronic component and a dissipation plate from which the relief protrudes. Advantageously, the contact surface is attached to the dissipation plate in such a way as to allow the surrounding atmosphere to pass between the dissipation plate and the contact surface. Alternatively or in combination with the protruding relief, the base plate can be merged with the relief and can comprise, for example, angles or undulations to maximize heat exchange.

Advantageously, the thermal switch comprises a shielding surface arranged recessed and around the contact surface so as to receive an electromagnetic shielding layer for the electronic component. Preferentially, this electromagnetic shielding layer is configured to surround the electronic component when the electronic component is in thermal contact with the contact surface and can be pierced so as to leave a free space at the center thereof for the contact surface.

Advantageously, the attachment elements are arranged to attach the electronic component between 3 mm and 30 mm from the base plate. Such a gap with the electronic component can allow optimized heat dissipation. For example, the electronic component is attached directly or through a printed circuit or an electronic board supporting it.

Another aspect of the present description relates to an electronic device comprising:
the heat sink assembly as described previously,
an electronic component, attached to the base plate so as to be in thermal contact with the thermal switch.

Another aspect of the present description relates to a method for manufacturing a heat sink assembly as previously described, comprising:
providing the base plate,
providing the heat sink,
assembling the heat sink to the base plate, so as to insert the thermal switch of the heat sink through the at least one opening in the base plate.

This method can allow the simple and inexpensive manufacture of a heat sink that is easy to integrate and offers high thermal performance.

Advantageously, the method comprises manufacturing the base plate by deep-drawing, which reduces the cost and the weight of the base plate. Provision may also be made for cutting and perforating steps.

Advantageously, the method comprises manufacturing the heat sink by extrusion, thereby obtaining a high level of thermal performance. Alternatively, the heat sink can be manufactured by molding or by machining or even a combination of these methods.

### DESCRIPTION OF THE FIGURES

Further features and advantages of the present description will become more clearly apparent from reading the following detailed description of embodiment(s) given by way of non-limiting example(s) and shown by the accompanying drawings, wherein:

FIG. 1 shows an exploded view of a heat sink assembly according to the present description with two electronic components;

FIG. 2 shows a view of a base plate according to the present description;

FIG. 3 shows an opposite view of a base plate according to FIG. 2;

FIG. 4 shows a profile view of a heat sink according to the present description;

FIG. 5 shows a three-quarter view of a heat sink according to FIG. 4;

FIG. 6 shows a heat sink assembly according to the present description in assembled configuration;

FIG. 7 shows an opposite view of the heat sink assembly according to FIG. 6;

FIG. 8 shows a heat sink assembly from FIG. 6 ready for mounting on a printed circuit.

A heat sink is an essential component used in the fields of electronics to effectively control the heat generated by various electrical apparatuses. This device plays the crucial role of balancing and dispersing the heat generated during the operation of components, such as semiconductors or microprocessors. Heat dissipation is fundamentally important, as it helps to maintain a critical temperature at which the apparatuses operate optimally without risk of failure.

Heat sinks are designed from a variety of heat-conductive materials, such as copper and aluminum, known for their excellent thermal conductivity. They can be manufactured as removable plates or integrated directly into electronic circuit designs. The aim is to transfer the heat to an external discharge point, such as a cold and ventilated surface or an external cooling source such as fresh air.

The usefulness of a heat sink in electronic apparatuses lies mainly in maintaining proper operation, extending their service life, improving performance and guaranteeing safety. Excessive heat can adversely affect the operation of components, resulting in reduced efficiency or even failure thereof. By effectively controlling the internal temperature, heat sinks help prevent these problems and ensure the long-term proper operation of electronic apparatuses.

Heat sinks can be obtained by extrusion: this manufacturing process generates profiles using a die and offers solutions for reducing the weight of heat sinks. The aluminum used in this manufacturing method is more thermally efficient than that used in injection molding. Furthermore, this method enables thinner thicknesses to be obtained, therefore considerably reducing the volume and the weight of the part. The disadvantage of extrusion is the obligation to make simple shapes. Indeed, it does not allow complex shapes to be made to serve as a structure notably for mechanically attaching electronic boards and for assembling mechanical parts.

Heat sinks can be obtained by molding, for example by injecting thermally conductive material such as aluminum or one of the alloys thereof into a mold. This manufacturing process can be used to manufacture complex parts, but it requires greater thicknesses, for example minimum thicknesses of 2 mm and draft angles of at least 3°. Furthermore, the aluminum alloy used for injection molding is less thermally efficient in comparison to extrusion. Heavy and expensive parts are thus obtained forming a heat sink with lower thermal performance and excess material in order to comply with the minimum thicknesses. On the other hand, it is possible to create a mechanical structure to be attached to the board or mechanical parts.

Finally, a deep-drawn plate can be used as a heat sink: deep-drawing is a simple and inexpensive manufacturing process that can be used to produce parts with a structure complex enough to allow the assembly of electronic boards and mechanical parts. However, it does not allow for a large number of fins to ensure a large heat exchange surface with the ambient air and thereby have good thermal performance. Thus, in the case of deep-drawn plates acting as heat sinks, their thermal performance remains fairly low.

A heat sink assembly according to the present description has been designed with these considerations in mind and includes a base plate and a heat sink independent of the base plate and nestable or arrangeable in the base plate. The heat sink is designed to be in thermal contact with an electronic component.

### Description of Embodiments

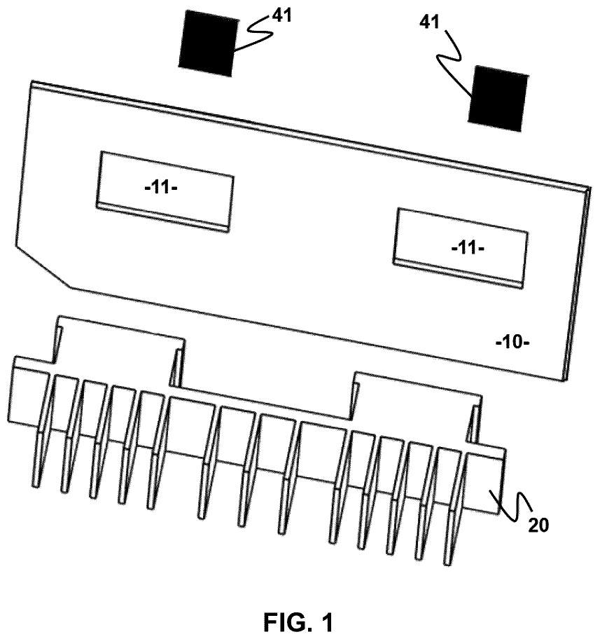

FIG. 1 shows a heat sink assembly comprising a base plate 10 comprising at least one, for example two openings 11, and a heat sink 20 configured to nest within the base plate 10, so as to contact at least one, for example two electronic components 41 located on an opposite face with respect to the heat sink 20.

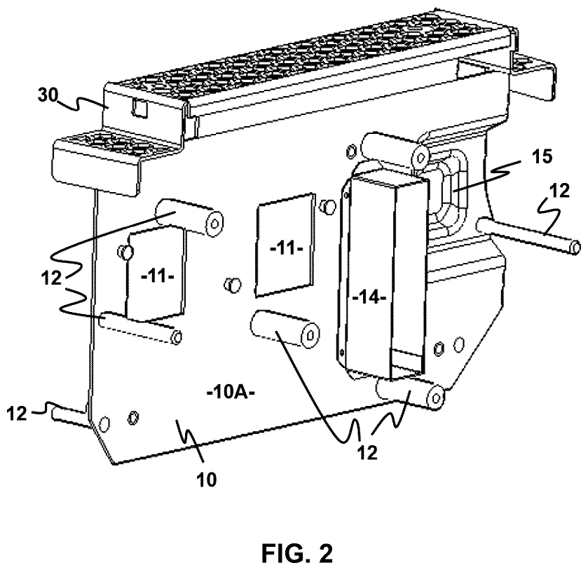

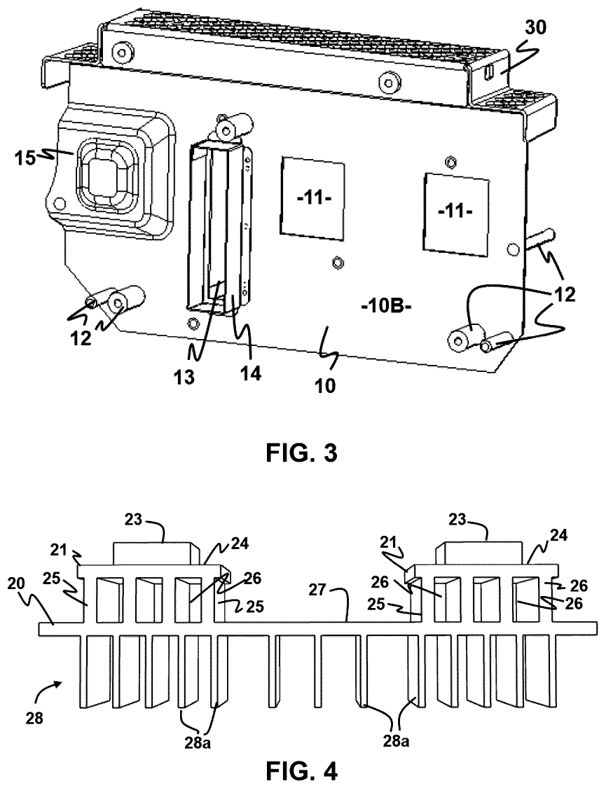

FIGS. 2 and 3 show the two faces of the base plate 10 comprising at least one opening 11 through the base plate 10, for example at least two openings 11. The openings 11 are for example square, but can have any geometry and are adapted to accommodate or nest at least part of the heat sink 20. For example, the base plate 10 may comprise a first face 10A and a second face 10B opposite the first face 10A.

The base plate 10 comprises at least one attachment element 12, for example a plurality of attachment elements 12. These attachment elements can be studs arranged to receive a screw or a rivet or else to be nested with another attachment element of another element to be attached to the base plate. Alternatively, the attachment elements 12 can take other forms such as through-holes or indentations for nesting.

The base plate 10 can comprise at least one further opening allowing the passage of an electrical connector or an electronic board, for example a communication opening 13. Such a communication opening 13 can be provided with an electromagnetic shielding element 14 if required, for example supported on the base plate 10. In the example shown in FIGS. 2 and 3, this electromagnetic shielding element 14 comprises two electromagnetic shielding sub-elements each placed on one of the first and second faces 10A, 10B.

Furthermore, at least one indentation 15 can be provided to accommodate a bulky element intended opposite the base plate 10. This indentation 15 can be a relief in the base plate 10, that is, a deformed portion defining a recess and releasing a volume allowing the bulky element to be accommodated and/or another element located opposite the opposite face of the base plate 10 to draw closer. Additionally, one surface of the indentation 15 can be in thermal contact with the bulky element or the other element if moderate heat dissipation is required. Thus, the base plate 10 can be adapted to different internal configurations of an electronic device and/or can allow direct heat dissipation for low-heat-generating electronic components.

Finally, other elements can be supported by the base plate 10, such as a ventilation grid 30 to allow hot air to escape from the electronic device, in order to allow or optimize the air flow on at least one of the faces, for example on both faces of the base plate 10. The ventilation grid 30 can be irregularly or anisotropically pierced to force the air flow in a certain direction and/or be provided with a sleeve or walls to direct the air flow. The ventilation grid 30 can also provide electromagnetic shielding to meet electromagnetic compatibility (EMC) requirements.

The base plate 10 therefore acts as a support or frame, allowing electronic elements and/or components to be attached and organized on both sides of the base plate 10. Furthermore, the base plate 10 is preferentially manufactured from a thermally conductive material such as metal, and can therefore contribute to a heat dissipation function with or without a heat sink. For example, the base plate 10 is a deep-drawn sheet, for example a preferentially stainless steel sheet, an aluminum alloy sheet, preferentially the 1xxx, 3xxx, 5xxxx series as known to the person skilled in the art or else a copper or brass sheet.

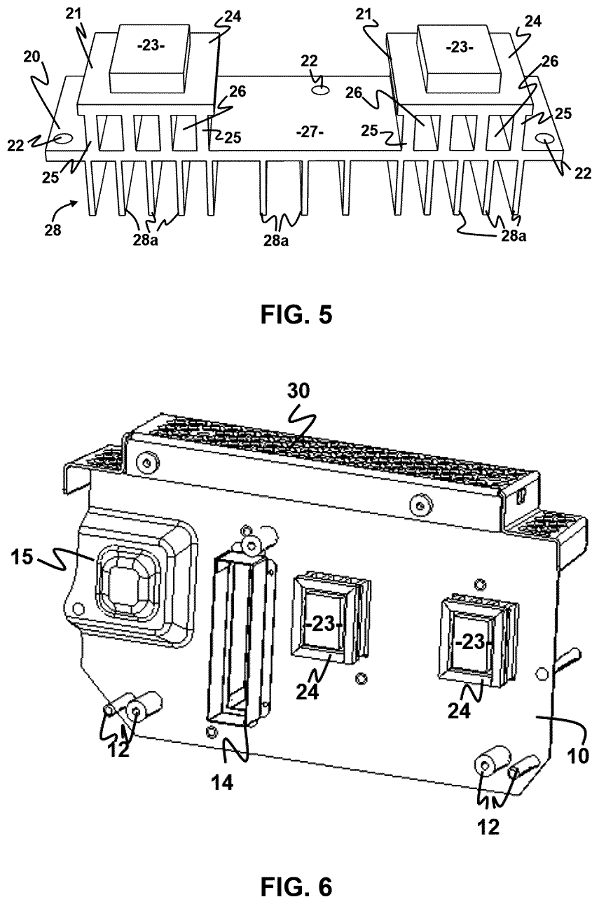

FIGS. 4 and 5 show two views of the heat sink 20. The heat sink comprises at least one thermal switch 21 arranged to be in thermal contact with an electronic component, for example two thermal switches 21 as shown in FIGS. 4 and 5. Furthermore, the heat sink 20 may comprise at least one anchor 22 arranged to allow an attachment to the base plate 10, for example through an attachment element 12 of the base plate 10 or another attachment element such as a rivet or a screw. FIG. 5 shows three anchors 22 in the form of through-holes.

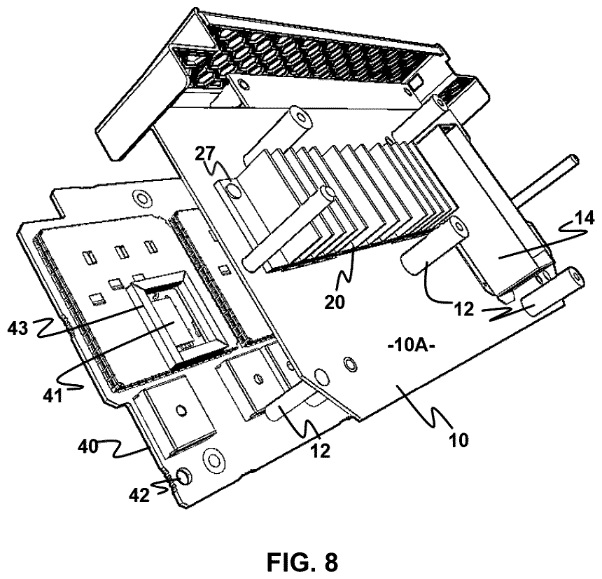

Preferentially, the at least one thermal switch 21 comprises a protruding contact surface 23, that is, positioned above a shielding surface 24. The contact surface is arranged to be in thermal contact with an electronic component and the optional shielding surface 24 is arranged to receive an electromagnetic shielding layer 43 as shown in FIG. 8. Alternatively, the top surface of the thermal switch 21 is intended to be in thermal contact with the electronic component 41. In this case, electromagnetic shielding can be provided around the thermal switch 21 if required.

The thermal switch 21 can protrude from a dissipation plate 27, and can be attached to this dissipation plate 27 so as to allow heat exchange with a surrounding environment. In FIGS. 4 and 5, such an attachment is achieved by strips 25 defining at least one channel 26 or tunnel between the dissipation plate 27 and the thermal switch 21, the channel allowing a flow of air or of gas to circulate, for example ambient air. Three channels 26 are visible below each thermal switch 21 in FIGS. 4 and 5.

On the dissipation plate 27, a relief 28 can optimize heat exchange with a surrounding environment. For example, the relief 28 protrudes from the face of the dissipation plate 27 opposite the face accommodating the thermal switch 21. The relief 28 may comprise a plurality of strips 28a or fins, or any other structure known to the person skilled in the art for maximizing solid/gas heat exchange, such as undulated structures, channels or studs. Alternatively or in combination, the dissipation plate 27 has a shape to optimize heat exchange, for example a non-planar shape with undulations or angles.

The heat sink 20 is preferentially manufactured in one piece from a thermally conductive material such as a metal, for example aluminum or an alloy with aluminum such as alloys 6063 and 1050. For example, the heat sink 20 is manufactured by extrusion. Alternatively, the heat sink 20 is manufactured by injection-molding, by machining or by a combination of these techniques. Other suitable materials for the heat sink 20 include copper, graphite, metal matrices (MMC) or else technical ceramics, for example based on aluminum nitride (AlN) or boron nitride (BN).

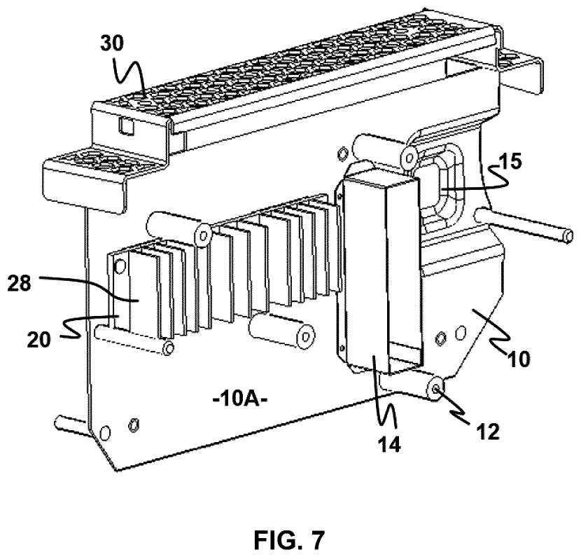

FIGS. 6 and 7 show a heat sink assembly according to the present description in assembled configuration. The dissipation plate 27 is thus attached to one face of the base plate 10 like the first face 10 A, for example by screws or rivets (see FIG. 7). The thermal switches 21 are passed through the corresponding openings 11 in the base plate 10, so as to protrude from the base plate 10 on the second face 10B, opposite the first face 10A whereupon the dissipation plate 27 of the heat sink 20 is attached. Preferentially, the dissipation plate 27 of the heat sink 20 can be attached in thermal contact with the base plate 10, for example in direct contact. Furthermore, the thermal switch 21 can be in thermal contact with the base plate 10, for example by direct thermal contact with at least one of the strips 25.

A method for manufacturing a heat sink assembly may comprise the following steps. The base plate can be manufactured, for example by deep-drawing a metal sheet, so as to create the at least one opening 11 and optionally the orifices required for example for the attachment elements 12 as well as the at least one optional communication opening 13 and the at least one optional indentation 15 depending on the specific application of the heat sink assembly. Furthermore, the base plate 10 can be cut to the correct dimensions. The attachment means 12, a ventilation grid 30 and/or at least one electromagnetic shielding element 14 can then be attached to the base plate 10, as required, or else after the assembly step described below.

At the same time as or else before or after the step hereinbefore, the heat sink 20 can be obtained, for example by injection molding, machining or preferentially by extrusion. The heat sink 20 is then assembled with the base plate 10 to obtain the heat sink assembly, by inserting the thermal switch 21 through the opening 11. An attachment step can be provided to attach the heat sink 20 to the base plate 10, for example by screwing, riveting or locking.

Once the heat sink 20 has been attached to the base plate 10, the thermal attachment assembly can be attached to an electronic component, either directly by attaching the electronic component to the base plate 10 by virtue of the attachment elements 12, or indirectly by attaching an electronic board 40 (PCB) supporting the electronic component 41 to the base plate 10 using the attachment elements 12, as shown in FIG. 8. For example, screws or rivets can be inserted through attachment orifices 42 in the electronic board and attached into the attachment elements 12, or else the attachment orifices 42 can nest into one end of the attachment elements 12.

The thermal switch 21 is then brought into thermal contact with the electronic component 41 either by direct contact or through a thermal gel or a layer of thermally conductive material, such as a silicone pad. Furthermore, an electromagnetic shielding layer 43 can be provided around the electronic component 41 and come into contact or be crushed by the shielding surface 24 so as to provide a good electromagnetic seal without impeding heat transfer.

The electronic component 41 and/or the electronic board 40 can thus be attached at a distance from the base plate 10, for example by virtue of attachment elements 12. For example, a gap of 3 to 30 mm, preferentially 6 to 24 mm and even more preferentially 11 to 19 mm is intended between the electronic component 41 and/or the electronic board 40 and the base plate. This spacing thus corresponds to a height of the heat sink 20 protruding from the base plate 10, for example the height of the thermal switch 21 and the strips 25 minus the thickness of the base plate 10. Alternatively or in combination, this spacing corresponds to a height of the attachment elements 12, for example measured from the base plate 10.

In an example not shown, a second electronic component or a second electronic board can be attached to the first face 10A opposite the electronic board 40. For example, this second electronic board may include electronic components that dissipate less heat than the electronic board 40, in which case a heat sink is not required. Heat dissipation can then take place naturally or else by simple thermal contact with the base plate 10.

If this is not possible, a second heat sink can be attached to the base plate 10, through further openings in the base plate (not shown) and in the opposite way with respect to the heat sink 20. In this fashion, at least two electronic boards can be mounted on both sides of the base plate. Furthermore, electrical or electronic communication between these at least two electronic boards can be ensured by a connector, a cable or an electronic communication board inserted through the communication opening 13, and for example surrounded by the electromagnetic shielding element 14.

The indentation 15 can accommodate an electronic component or any other bulky element on one face of the base plate and/or provide moderate heat dissipation for this electronic element, through thermal contact between one surface of the indentation 15 and this electronic component. Furthermore, the base plate 10 can itself be attached to a casing or a frame and/or attach accessory elements such as wiring, one or more fans and/or elements of a liquid cooling system (not shown).

The base plate 10 therefore has a structural function by supporting and attaching the heat sink 20 and the electronic board 40 and/or the electronic component 41. It thus makes an electronic device lighter and simpler to manufacture by minimizing the number of elements needed to attach electronic components and to dissipate the heat generated, at reduced cost. The heat sink can be optimized for heat dissipation, without taking into account mechanical constraints. It can be manufactured by a method different to that of the base plate, for example by extrusion, and thus allow optimum heat exchange.

During operation, the electronic component 41 will generate heat and this heat will be transmitted to the heat sink 20, allowing optimum heat exchange with the surrounding environment via the relief 28 and preferentially the dissipation plate 27, the strips 25 and the at least one channel 26.

Additionally, the base plate 10 is preferentially manufactured from a thermally conductive material and is preferentially in thermal contact with the heat sink 20, thereby increasing the exchange surface and thus optimizing the transfer of thermal energy generated by the electronic component to the external environment.

### INDUSTRIAL APPLICABILITY

A heat sink assembly according to the present description, and manufacture thereof, are capable of industrial application in order to structure and ensure heat exchange in any type of electronic apparatus having any type of electronic component.

A non-exhaustive list of electronic apparatuses wherein one or more embodiments are likely to be implemented comprises computers, graphics cards, computer servers, routers, internet or WAN access gateways, network switches, televisions, computer screens, set-top boxes, audio power amplifiers, dimmers for high- power LED lighting, power supplies for computers and other electronic apparatuses, fast chargers for smartphones and tablets, inverters for uninterruptible power supply systems, electric motor controllers for electric vehicles and industrial equipment, high-power electrical transformers, RF amplifiers for wireless communication equipment, voltage regulators for power electronics, electric vehicles, renewable energy systems and battery energy storage systems.

A non-exhaustive list of electronic components comprises general-purpose processors (CPU) and/or dedicated processors (DSP, FGPA, etc.) for desktops, notebooks, servers, switches and routers, graphics processors (GPUs) for desktops, notebooks and servers, gateways, multimedia equipment, memory modules (RAM) for desktops, switches, routers, notebooks and servers, power transistors (MOSFETS, IGBTs, BJTs), power diodes (Schottky diodes, PIN diodes), linear voltage regulators (LDO, low-dropout regulators), switching voltage regulators (Buck, Boost, Buck-Boost), operational power amplifiers, thyristors (SCR, TRIAC), silicon-controlled rectifiers (SCR), IGBT modules for frequency inverters and inverters, power resistors (wound resistors, thick-film resistors), power inductors (iron-core inductors, ferrite-core inductors), power transformers (high-frequency transformers, low-frequency transformers), power LED modules for lighting, electric motors, power modules for telecommunications equipment (RF amplifiers, transceivers), power modules for medical equipment (ultrasound amplifiers, X-ray generators) and power modules for welding equipment (welding inverters, welding rectifiers).

It will be understood that various modifications and/or improvements obvious to the person skilled in the art may be made to the various embodiments of the description disclosed in the present description without departing from the scope of the description.

In particular, it may be noted that the base plate is not limited to a specific shape or dimensions, but can be adapted according to the desired application. The heat sink can have any suitable shape and in particular any type of relief. The thermal switch can have any suitable shape and is not limited to a parallelepiped. Several base plates can be attached together and each base plate can comprise one or more heat sinks, attached in a parallel or staggered manner to one or both sides of the base plate.

1. A heat sink assembly comprising:
a. a base plate comprising at least one opening and at least one attachment element for maintaining an electronic component opposite the at least one opening, and
b. a heat sink independent of the base plate and comprising at least one thermal switch inserted through the at least one opening and arranged to be in thermal contact with the electronic component; and
wherein the heat sink is provided in one piece and comprises at least one relief opposite the thermal switch, the relief being configured to maximize heat exchange with the surrounding atmosphere; the thermal switch comprising a contact surface arranged to be in thermal contact with the electronic component and a dissipation plate from which the relief protrudes, the contact surface being attached to the dissipation plate so as to allow the surrounding atmosphere to pass between the dissipation plate and the contact surface.

2. The heat sink assembly according to claim 1, wherein the thermal switch comprises a shielding surface arranged recessed and around the contact surface so as to receive an electromagnetic shielding layer for the electronic component.

3. The heat sink assembly according to claim 1, wherein the attachment elements are arranged to attach the electronic component between 3 mm and 30 mm from the base plate.

4. An electronic device comprising:
the heat sink assembly according to claim 1; and
an electronic component, attached to the base plate so as to be in thermal contact with the thermal switch.

5. A method for manufacturing a heat sink assembly according to claim 1 comprising:
providing the base plate,
providing the heat sink,
assembling the heat sink to the base plate, so as to insert the thermal switch of the heat sink through the at least one opening in the base plate.

6. The manufacturing method according to claim 5, comprising manufacturing the base plate by deep drawing.

7. The manufacturing method according to claim 6, comprising manufacturing the heat sink by extrusion.

8. Use of a heat sink assembly according to claim 1, for dissipating thermal energy from an electronic component.
